(19) United States
(12) Patent Application Publication
(10) Pub. No.: US 2025/0185315 A1
(43) Pub. Date: Jun. 5, 2025

(54) CONNECTING FRONTSIDE CONTACT WITH BACKSIDE CONTACT OF A SOURCE/DRAIN

(71) Applicant: International Business Machines Corporation, Armonk, NY (US)

(72) Inventors: Andrew M. Greene, Slingerlands, NY (US); Ruilong Xie, Niskayuna, NY (US); Julien Frougier, Albany, NY (US); Nicolas Jean Loubet, GUILDERLAND, NY (US)

(21) Appl. No.: 18/529,460

(22) Filed: Dec. 5, 2023

(51) Int. Cl. H01L 29/06; H01L 21/8234; H01L 23/522; H01L 23/528; H01L 27/088; H01L 29/08; H01L 29/423; H01L 29/66; H01L 29/775; H01L 29/786

(52) U.S. Cl. CPC H10D 62/121; H01L 23/5226; H01L 23/5286; H10D 30/014; H10D 30/43; H10D 30/6735; H10D 30/6757; H10D 62/151; H10D 64/017; H10D 84/013; H10D 84/0149; H10D 84/0151; H10D 84/038; H10D 84/83

(57) ABSTRACT

Embodiments disclosed herein include a semiconductor structure. The semiconductor structure may include a first source/drain (S/D) epitaxially grown in a device layer, a frontside contact contacting a frontside of the first S/D, a backside contact contacting a backside of the first S/D, and a via contact contacting: i) a sidewall of the first S/D, ii) the frontside contact, and iii) the backside contact.

### BACKGROUND

The present invention relates generally to the field of semiconductor device manufacturing, and more particularly to fabricating a sidewall via that connects a frontside contact to a backside contact along a sidewall of a source/drain epi.

High-performance transistors benefit from advanced techniques for optimizing source and drain regions on both the frontside and backside of the semiconductor substrate. On the frontside, extension implants middle of line (MOL) epitaxy implantation, activation anneal and silicide formations extension or halo implants are commonly used. Extension implants create shallow, highly doped regions to mitigate short-channel effects and enhance control of the channel under the gate. Silicide formation reduces contact resistance, improving current flow and transistor speed.

On the backside, options vary based on technology and requirements. Through-silicon vias (TSVs) enable vertical connections to the backside for 3D integrated circuits and efficient heat dissipation. Backside doping can modify substrate properties, and thermal management solutions like heat spreaders or heat sinks help dissipate heat. Designers consider factors like power efficiency, thermal management, and reliability when selecting the most suitable methods for high-performance transistors. Optimizing source and drain regions on the frontside involves techniques like extension implants, middle of line (MOL) Epitaxy implantation, activation anneal and silicide formations extension or halo implants to enhance transistor performance. On the backside, solutions like TSVs, backside doping, and thermal management address specific needs, depending on the technology and application.

### SUMMARY

Aspects of an embodiment of the present invention include a semiconductor structure. The semiconductor structure may include a first source/drain (S/D) epitaxially grown in a device layer, a frontside contact contacting a frontside of the first S/D, a backside contact contacting a backside of the first S/D, and a via contact contacting: i) a sidewall of the first S/D, ii) the frontside contact, and iii) the backside contact.

Aspects of an embodiment of the present invention encompass a method of fabricating a semiconductor structure. The method may include forming a first source/drain (S/D) in a device layer, forming a frontside contact contacting a frontside of the first S/D, forming a backside contact contacting a backside of the first S/D, and forming a via contact contacting: i) a sidewall of the first S/D, ii) the frontside contact, and iii) the backside contact.

Aspects of an embodiment of the present invention include a semiconductor structure. The semiconductor structure may include a semiconductor structure that has a first source/drain (S/D) grown in a device layer and a first contact contacting the first S/D on a frontside, a backside, and a sidewall.

### BRIEF DESCRIPTION OF THE DRAWINGS

FIG. 1 depicts a schematic top view of a semiconductor structure at a stage of fabrication, in accordance with one embodiment of the present invention.

FIG. 2 depicts a cross-sectional side view of the semiconductor structure of FIG. 1 along line B-B′, with like reference numerals referring to like features at a fabrication stage of the processing method, in accordance with one embodiment of the present invention.

FIG. 3 depicts a cross-sectional side view of the semiconductor structure of FIG. 1 along line B-B′ at a subsequent fabrication stage of the processing method, in accordance with one embodiment of the present invention.

FIG. 4 depicts a cross-sectional side view of the semiconductor structure of FIG. 1 along line B-B′ at a subsequent fabrication stage of the processing method, in accordance with one embodiment of the present invention.

FIG. 5 depicts a cross-sectional side view of the semiconductor structure of FIG. 1 along line B-B′ at a subsequent fabrication stage of the processing method, in accordance with one embodiment of the present invention.

FIGS. 6A and 6B depict cross-sectional side views of the semiconductor structure of FIG. 1 along line A-A′ and B-B′ at a subsequent fabrication stage of the processing method, in accordance with one embodiment of the present invention.

FIGS. 7A and 7B depict cross-sectional side views of the semiconductor structure of FIG. 1 along line A-A′ and B-B′ at a subsequent fabrication stage of the processing method, in accordance with one embodiment of the present invention.

FIGS. 8A and 8B depict cross-sectional side views of the semiconductor structure of FIG. 1 along line A-A′ and B-B′ at a subsequent fabrication stage of the processing method, in accordance with one embodiment of the present invention.

FIGS. 9A and 9B depict cross-sectional side views of the semiconductor structure of FIG. 1 along line A-A′ and B-B′ at a subsequent fabrication stage of the processing method, in accordance with one embodiment of the present invention.

FIGS. 10A and 10B depict cross-sectional side views of the semiconductor structure of FIG. 1 along line A-A′ and B-B′ at a subsequent fabrication stage of the processing method, in accordance with one embodiment of the present invention.

FIGS. 11A and 11B depict cross-sectional side views of the semiconductor structure of FIG. 1 along line A-A′ and B-B′ at a subsequent fabrication stage of the processing method, in accordance with one embodiment of the present invention.

FIGS. 12A and 12B depict cross-sectional side views of the semiconductor structure of FIG. 1 along line A-A′ and B-B′ at a subsequent fabrication stage of the processing method, in accordance with one embodiment of the present invention.

FIGS. 13A and 13B depict cross-sectional side views of the semiconductor structure of FIG. 1 along line A-A′ and B-B′ at a subsequent fabrication stage of the processing method, in accordance with one embodiment of the present invention.

FIGS. 14A and 14B depict cross-sectional side views of the semiconductor structure of FIG. 1 along line A-A′ and B-B′ at a subsequent fabrication stage of the processing method, in accordance with one embodiment of the present invention.

FIGS. 15A and 15B depict cross-sectional side views of the semiconductor structure of FIG. 1 along line A-A′ and B-B′ at a subsequent fabrication stage of the processing method, in accordance with one embodiment of the present invention.

FIGS. 16A and 16B depict cross-sectional side views of the semiconductor structure of FIG. 1 along line A-A′ and B-B′ at a subsequent fabrication stage of the processing method, in accordance with one embodiment of the present invention.

FIGS. 17A and 17B depict cross-sectional side views of the semiconductor structure of FIG. 1 along line A-A′ and B-B′ at a subsequent fabrication stage of the processing method, in accordance with one embodiment of the present invention.

FIGS. 18A and 18B depict cross-sectional side views of a semiconductor structure at a fabrication stage of a processing method, in accordance with one embodiment of the present invention.

### DETAILED DESCRIPTION

In the following detailed description, reference is made to the accompanying drawings, which show specific examples of embodiments of the invention. These embodiments are described in sufficient detail to enable those skilled in the art to practice them, and it is to be understood that other embodiments may be utilized, and that structural, logical, and electrical changes may be made without departing from the described embodiments. The following detailed description is, therefore, not to be taken in a limiting sense, and the included embodiments are defined by the appended claims.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

References in the specification to “one embodiment,” “an embodiment,” “certain embodiments,” etc., indicate that the embodiment described may include a particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “right,” “left,” “vertical,” “horizontal,” “top,” “bottom,” and derivatives thereof shall relate to the disclosed structures and methods, as oriented in the drawing Figures. The terms “above,” “below,” “positioned on,” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

It will be understood that when an element as a layer, region or substrate is referred to as being “on” or “over” another element, it can be directly on the other element or intervening elements may also be present. In contrast, when an element is referred to as being “directly adjacent,” “directly on,” or “directly over” another element, there are no intervening elements present. It will also be understood that when an element is referred to as being “beneath” or “under” another element, it can be directly below or under the other element, or intervening elements may be present. Additionally, when an element is referred to as being “directly below” or “directly above” another element, intervening elements may be present, but the elements overlap at least partially relative to a vertical axis perpendicular to a major surface. With regard to the fabrication of transistors and integrated circuits, major surface refers to that surface of the semiconductor layer in and about which a plurality of transistors are fabricated, e.g., in a planar process. As used herein, the term “vertical” means substantially orthogonal with respect to the major surface and “horizontal” means substantially parallel to the major surface. Typically, the major surface is along a plane of a monocrystalline silicon layer on which transistor devices are fabricated. Each reference number may refer to an item individually or collectively as a group. For example, a contact 202 may refer to a single contact 202 or multiple contacts 202.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. In some embodiments, epitaxial growth and/or deposition processes can be selective to forming on semiconductor surfaces, and may or may not deposit material on other exposed surfaces, such as silicon dioxide or silicon nitride surfaces.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used, and structural or logical changes may be made, without departing from the spirit and scope defined by the claims. The description of the embodiments is not limiting. In particular, elements of the embodiments described hereinafter may be combined with elements of different embodiments.

In some embodiments, etching mask layer(s) may be provided, and the layers that are not protected thereby are removed. For example, as is understood in the art, a mask layer, sometimes referred to as a photomask, may be provided by forming a layer of photoresist material on another layer, exposing the photoresist material to a pattern of light, and developing the exposed photoresist material. An etching process, such as a reactive ion etch (RIE), may be used to form patterns (e.g., openings) by removing portions of another layer. After etching, the mask layer may be removed using a conventional plasma ashing or stripping process. Accordingly, the pattern of the mask layer facilitates the removal of another layer, such as an amorphous SiO2 layer and/or a conductive oxide diffusion barrier, for example, in areas where the mask layer has not been deposited.

For the sake of brevity, conventional techniques related to semiconductor structure and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor structures and semiconductor-based ICs are well known and so, in the interest of brevity, many conventional steps will only be mentioned briefly herein or will be omitted entirely without providing the well-known process details.

Improvements in the design of integrated circuits (IC) have enabled feature sizes for transistors in a device layer to enter into deep submicron and nanometer regime. Embodiments herein recognize benefits from separating the power delivery components from the signal wires. A backside power delivery network (BSPDN) and/or backside power rails (BPR), for example, can greatly improve the routability for field-effect transistor (FET). Improving routability means the design of the IC provides easier connection between source/drains (S/Ds), gates, etc. and the other components of the IC. The embodiments herein also recognize that the decrease in feature size can mean that the electrical connection between the S/Ds and the other components decreases performance due to the small contact area connecting the S/Ds to the metallized contacts.

The embodiments described herein, therefore, are fabricated with electrical connection on all sides of an epitaxial S/D. The electrical connection may be fabricated as multiple parts of a contact: a frontside contact, a backside contact, and a via contacts that may include electrical contact formation also including the epitaxial S/D sidewalls and bottom surfaces. The contact on sides and/or bottom of the S/D enables an increased surface area for conveying an electric signal between the contact(s) and the S/D. Specifically, certain embodiments may include a semiconductor structure that has a first source/drain (S/D) epitaxially grown in a device layer, a frontside contact contacting a frontside of the first S/D, a backside contact contacting a backside of the first S/D, and a via contact contacting: i) a sidewall of the first S/D, ii) the frontside contact, and iii) the backside contact. The via contact provides the technical benefit of increased area of contact between the via contact and the first S/D such that the performance (e.g., speed, efficiency, low-resistivity) may be improved in the operation of the semiconductor structure.

Certain embodiments may further include a shallow trench isolation (STI), and a STI spacer liner and a STI liner surrounding the STI. The STI spacer liner and STI liner provide the technical benefit of alignment of the contacts during fabrication of the semiconductor structure. That is, with a premium placed on the space between devices, the STI spacer liner and STI liner allow the via contact to be fabricated directly adjacent to the S/D even if the lithographic alignment is imperfect. Certain embodiments of the semiconductor structure may include via contacts that are etched into the STI spacer liner and not etched into the STI liner to ensure that the via contact is deep enough to connect to the backside contact, but not too deep. Too deep means, for example, that the via contact protrudes passed the STI and/or into the fabrication substrate. Certain embodiments of the semiconductor structure may further include a second STI. The backside contact is confined by the STI liner and the second STI, which provides the technical benefit of self-alignment when the backside contact is metalized. Certain embodiments of the semiconductor structure may include a second STI liner. The backside contact is confined by the STI liner and the second STI liner to provide the technical benefit once again of self-alignment when the backside contact is metalized.

Certain embodiments of the semiconductor structure may include a second via contact contacting a second sidewall of the first S/D. Two via contacts provide the technical benefit of further increase in area of contact between the S/D and the contacts, which increases performance of the semiconductor structure due to decreased resistivity and accompanying higher current flow. Certain embodiments of the semiconductor structure may include a backside power delivery network (BSPDN) connected to the backside contact, and a back-end-of-line (BEOL) connected to the frontside contact. Having both a BSPDN and a BEOL increases the cell density of the semiconductor structure, potentially doubling the number of FETs that could be coupled to power and signal processing.

Certain embodiments of the present invention may include methods of fabricating a semiconductor structure. The methods may include stages such as forming a first source/drain (S/D) in a device layer, forming a frontside contact contacting a frontside of the first S/D, forming a backside contact contacting a backside of the first S/D, and forming a via contact contacting: i) a sidewall of the first S/D, ii) the frontside contact, and iii) the backside contact. The via contact provides the technical benefit of increased area of contact between the via contact and the first S/D such that the performance (e.g., speed, efficiency, low-resistivity) may be improved in the operation of the semiconductor structure.

Certain embodiments may include the frontside contact and the via contact being metalized in one fabrication step, which is beneficial for efficiently fabricating the frontside contact and the via contact temporally. The method may include forming an STI liner, forming a shallow trench isolation (STI) within the STI liner, recessing the STI liner, and forming an STI spacer liner in the recess of the STI liner. The STI spacer liner and STI liner provide the technical benefit of alignment of the contacts during fabrication of the semiconductor structure. That is, with a premium placed on the space between devices, the STI spacer liner and STI liner allow the via contact to be fabricated directly adjacent to the S/D even if the lithographic alignment is imperfect.

Certain embodiments of the present invention may also include a semiconductor structure that has a first source/drain (S/D) grown in a device layer and a first contact contacting the first S/D on a frontside, a backside, and a sidewall. The contact contacting the frontside, backside, and a sidewall provides the technical benefit of increased area of contact between the via contact and the first S/D such that the performance (e.g., speed, efficiency, low-resistivity) may be improved in the operation of the semiconductor structure.

The present invention and an example fabrication process will now be described in detail with reference to the Figures.

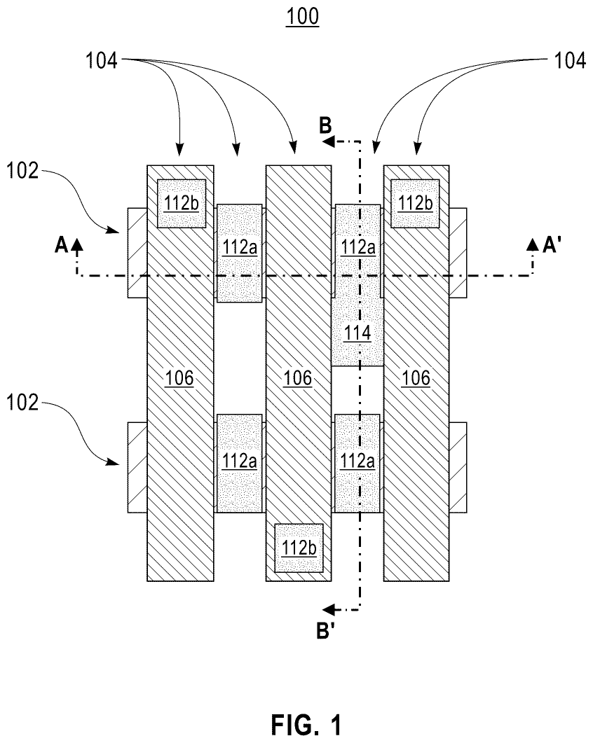

FIG. 1 depicts a schematic top view of a semiconductor structure 100 at a stage of fabrication, in accordance with one embodiment of the present invention. The semiconductor structure 100 is organized as rows 102 and columns 104 of field-effect transistor (FET) devices 106 fabricated in a device layer of the semiconductor device 100. The columns 104 include gates that control channels between S/Ds of the FET devices 106. The semiconductor structure 100 also includes contacts 112a, b that electrically connect the S/Ds and gates to a back-end-of-line (BEOL) interconnect network on a front side of the semiconductor structure 100 or to a backside power delivery network (BSPDN) on a back side of the semiconductor structure 100. Specifically, S/D contacts 112a connect the S/Ds to the BEOL or the BSPDN; and gate contacts 112b connect the gates 108 to the BEOL. Certain sections of the S/D contacts 112a may include a via contact 114 that enables the S/D contact 112a to wrap around the S/D, for example wrapping around three of four sides of the S/D. The semiconductor structure 100 includes other components (e.g., shallow trench isolation, interlayer dielectric) that are not illustrated in FIG. 1 so that the rows and columns of the semiconductor structure 100 may be more easily described.

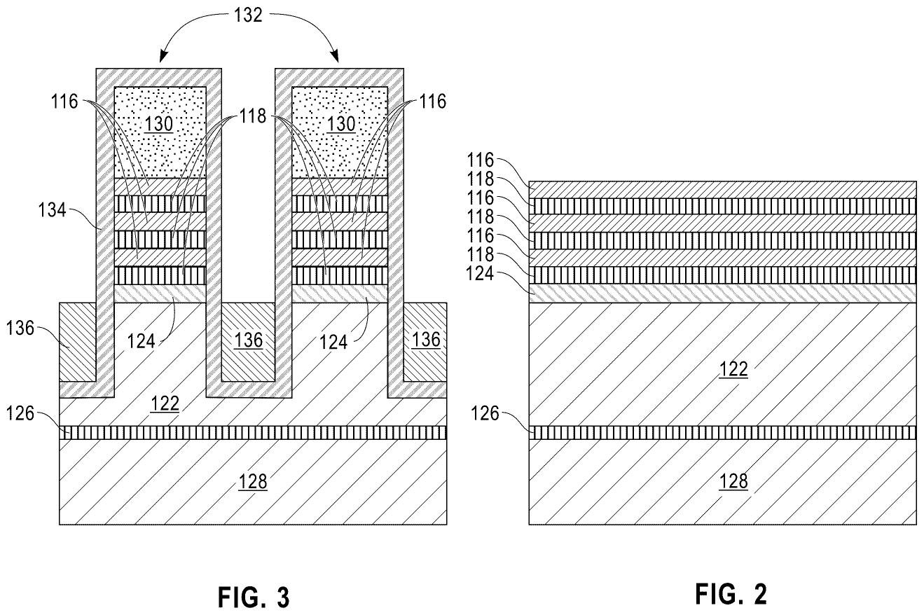

FIG. 2 depicts a cross-sectional side view of the semiconductor structure 100 of FIG. 1 along line B-B′, with like reference numerals referring to like features at a fabrication stage of the processing method, in accordance with one embodiment of the present invention. The semiconductor structure 100 includes nanosheets 116 and sacrificial semiconductor layers 118 that are formed in an alternating series on a substrate 122. The nanosheets 116 may be composed of a semiconductor material, such as silicon (Si). The sacrificial semiconductor layers 118 may be composed of a second semiconductor material, such as silicon germanium (SiGe). The semiconductor structure 100 may also include a third material as a bottom sacrificial layer 124 just above the substrate 122. The nanosheets 116, sacrificial semiconductor layers 118, and bottom sacrificial layer 124 may be formed by an epitaxial growth process, and at least the sacrificial semiconductor layers 118 may be undoped. The semiconductor material of the sacrificial semiconductor layers 118 is selected to be removed cleanly from the semiconductor material of the nanosheets 116. As used herein, the term “cleanly” in reference to a material removal process (e.g., etching) denotes that, with an appropriate etchant choice, the material removal rate (i.e., etch rate) for the targeted material is greater than the removal rate for at least another material exposed to the material removal process. The bottom sacrificial semiconductor layer 124 may have a different silicon germanium ratio that enables a fabrication operator to cleanly remove the bottom sacrificial layer 124 without removing the other sacrificial semiconductor layers 118 or the nanosheets 116. The number of nanosheets 116 and sacrificial semiconductor layers 118 may differ (more layers or fewer layers) from the number depicted in the representative embodiment.

The semiconductor structure 100 may also include an etch stop layer 126 and a structural substrate 128 that are not necessarily drawn to scale. Function and utility of the etch stop layer 126 and structural substrate 128 will be explained in detail below.

FIG. 3 depicts a cross-sectional side view of the semiconductor structure 100 of FIG. 1 along line B-B′ at a subsequent fabrication stage of the processing method, in accordance with one embodiment of the present invention. The semiconductor structure 100 includes a hardmask 130 formed on the top surface of the nanosheets 116. The hardmask 110 may be composed of a hardmask material, such as silicon nitride, that is deposited (e.g., by chemical vapor deposition (CVD)) and patterned using a lithographic patterning process. The patterning enables the semiconductor structure 100 to be formed as fins 132 that will define the channel region of each of the FET devices 106. The etching to form the fins 132 may carry further into the substrate 122 as well such that a portion of the substrate 122 is formed into the fins 132, and the substrate 122 also includes the gap between the fins 132.

After the fins 132 are etched using the hardmask 130, an STI liner 134 is deposited as a blanket layer over the fins 132 and the substrate 122. The STI liner 134 may include a dielectric material such as silicon nitride. A shallow trench isolation (STI) 136 is also deposited to fill the gap between the fins 132. The STI 136 may then be recessed such that the STI 136 is only present between the gaps in the substrate 122 and is etched from the gaps between the nanosheets 116.

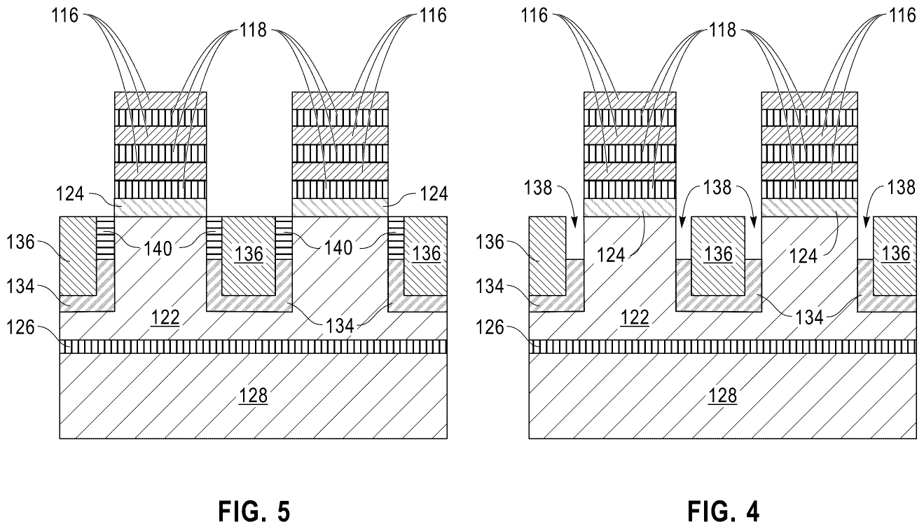

FIG. 4 depicts a cross-sectional side view of the semiconductor structure 100 of FIG. 1 along line B-B′ at a subsequent fabrication stage of the processing method, in accordance with one embodiment of the present invention. The semiconductor structure 100 is etched with an etch process that selectively etches the STI liner 134. The selective etch process is controlled to etch a spacer gap 138 in the space between the substrate 122 and the STI 136. The process is controlled using the time, concentration, and chemistry of the etch process. That is, the etch process is stopped (for example, a wet etch product is removed from the semiconductor structure 100) when the spacer gap 138 is calculated to be the correct depth, and the STI liner 134 has been removed completely from the nanosheets 116 and the sacrificial layers 118. The hardmask 130 may also be removed from the top of the fins 132 using a selective etch process that does not affect the nanosheets 116 or the sacrificial layers 118.

FIG. 5 depicts a cross-sectional side view of the semiconductor structure 100 of FIG. 1 along line B-B′ at a subsequent fabrication stage of the processing method, in accordance with one embodiment of the present invention. The semiconductor structure 100 includes a STI spacer liner 140 filled into the spacer gap 138 and polished/etched to be flush with the top of the STI 136. The STI spacer liner 140 is formed using a material that is different from and etch selective to the STI liner 134. For example, the material of the STI spacer liner 140 may also be a dielectric material, but may be made from silicon oxycarbide rather than the silicon nitride of the STI liner 134.

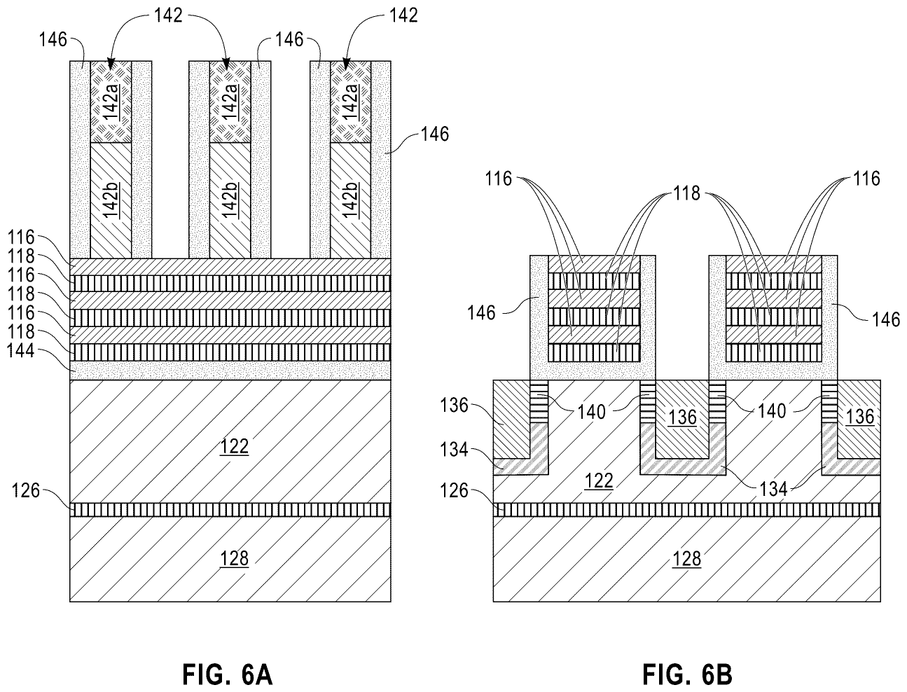

FIGS. 6A and 6B depict cross-sectional side views of the semiconductor structure 100 of FIG. 1 along line A-A′ and B-B′ at a subsequent fabrication stage of the processing method, in accordance with one embodiment of the present invention. The semiconductor structure 100 includes dummy gates 142 formed on top of the fins 132 to mark the location for the formation of the gates of the FET devices 106. The dummy gates 142 include a top hard mask 142a and a bottom dummy gate structure 142b (i.e., only shown in FIG. 6A). The top hard mask 142a may be formed from hard mask materials of any variety, since the dummy gate 142 is removed before fabrication of the semiconductor structure 100 is completed. The bottom dummy gate structure 142b may include a thin silicon oxide layer followed by amorphous silicon that is patterned by conventional litho and etch process. The bottom sacrificial layer 124 may be replaced at this stage with a bottom dielectric isolation (BDI) 144. The material of the BDI 144 also forms spacers 146 around the sides of the fins 132 and the dummy gates 142.

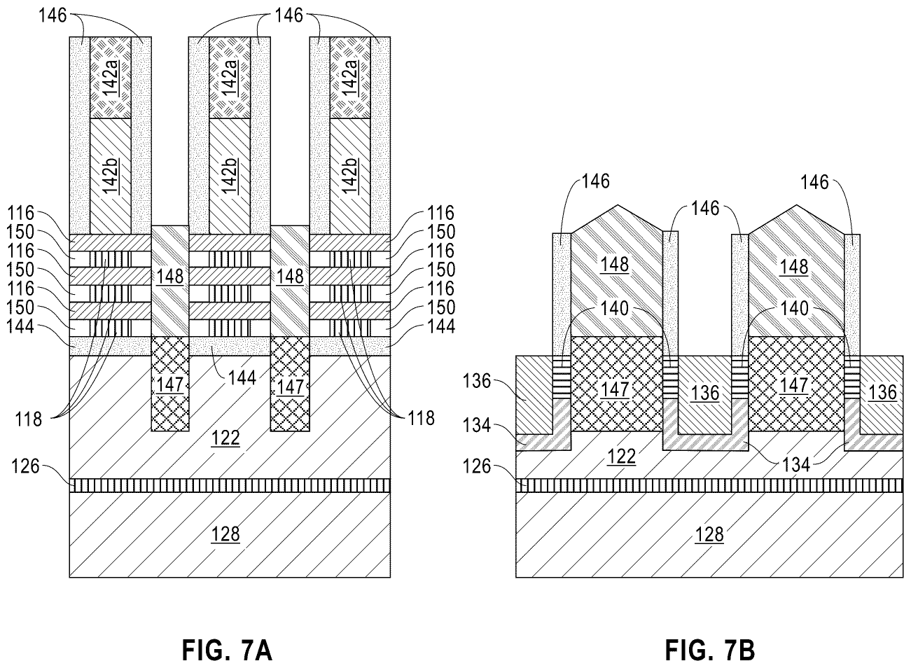

FIGS. 7A and 7B depict cross-sectional side views of the semiconductor structure 100 of FIG. 1 along line A-A′ and B-B′ at a subsequent fabrication stage of the processing method, in accordance with one embodiment of the present invention. The semiconductor structure 100 includes placeholders 147 and source/drains (S/Ds) 148 that are formed in gaps between the dummy gates 142. To create space for the placeholders 147 and the S/Ds 148, the semiconductor structure 100 may be etched with a directional etch such as reactive ion etch (RIE) that etches portions of the nanosheets 116, sacrificial layers 118, and substrate 122. The material for the placeholders 147 is then deposited in the etched gap, followed by any needed recessing of the placeholders 147 to expose all of the nanosheets 116, and then epitaxial growth of the S/Ds 148. Before formation of the S/Ds 148, the sacrificial layers 118 may be recessed, with the resulting recesses being filled with inner spacers 150. The inner spacer 150 may include silicon nitride (SiN), silicon boron carbon nitride (SiBCN), silicon oxygen carbon nitride, (SiOCN), silicon oxygen carbide (SiOC), or other materials and are formed around where the sacrificial semiconductor layers 118 were indented. Formation of the S/Ds 148 may include ion implant steps that reduce the contact resistance between the contacts and the S/Ds 148. Implanting involves bombarding the exposed regions of the S/Ds 148 with high-energy ions of a dopant material, such as boron or phosphorus, to create n-type or p-type regions.

The implantation can be done vertically or at an angle, depending on the desired shape and depth of the source/drain regions. Vertical implantation is usually done first, to create a uniform doping profile across the S/Ds 148. This can be achieved by using a mask that covers the gate and the spacers, and exposing the S/Ds 148 to a beam of ions that is perpendicular to the wafer surface. The dose and energy of the ions are carefully controlled to achieve the desired junction depth and concentration. Angled implantation is done after vertical implantation, to create a lateral doping profile that can reduce the contact resistance by increasing the effective area of the S/Ds 148. Angled implantation can be done by tilting the wafer at an angle, such as 45 degrees, and exposing it to a beam of ions. The angle, dose and energy of the ions are also carefully controlled to achieve the desired lateral extension and concentration. Certain embodiments may also include backside contact ion implant as a potential option to improve contact resistivity.

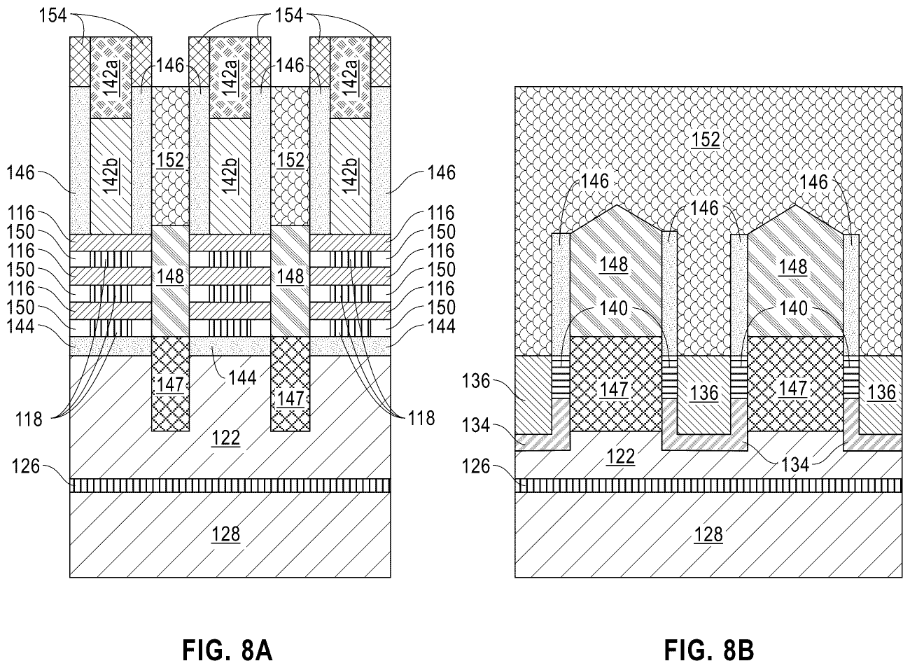

FIGS. 8A and 8B depict cross-sectional side views of the semiconductor structure 100 of FIG. 1 along line A-A′ and B-B′ at a subsequent fabrication stage of the processing method, in accordance with one embodiment of the present invention. The semiconductor structure 100 includes an organic planarization layer (OPL) 152 that acts as a mask for the removal and replacement of portions of the spacers 146 with a protective spacer 154 over the dummy mask 142.

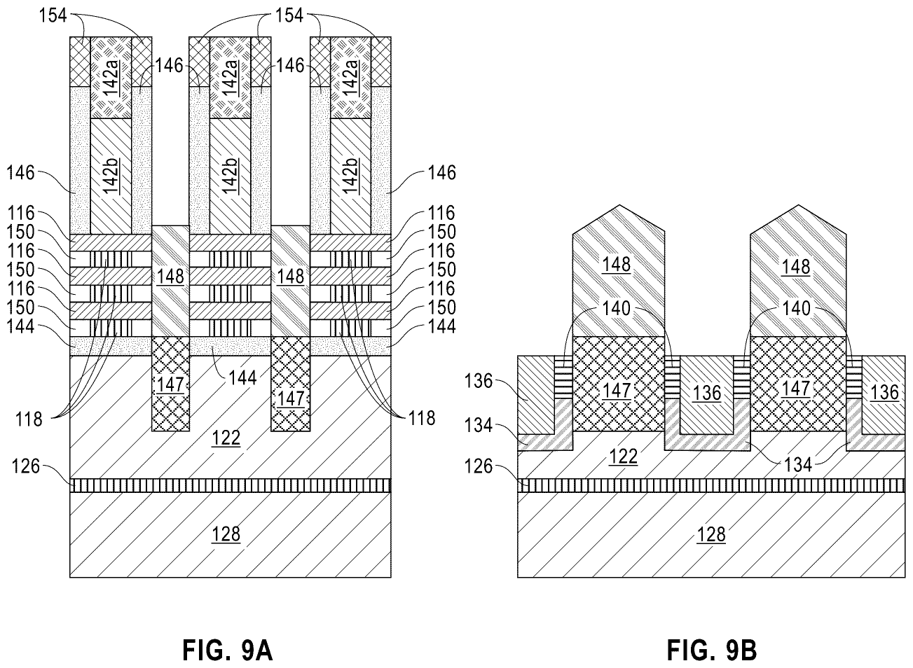

FIGS. 9A and 9B depict cross-sectional side views of the semiconductor structure 100 of FIG. 1 along line A-A′ and B-B′ at a subsequent fabrication stage of the processing method, in accordance with one embodiment of the present invention. The semiconductor structure 100 has the OPL 152 removed and shows that the protective spacers 154 protect the spacers 146 of the dummy gate 142 while the spacers 146 around the S/Ds 148 are removed.

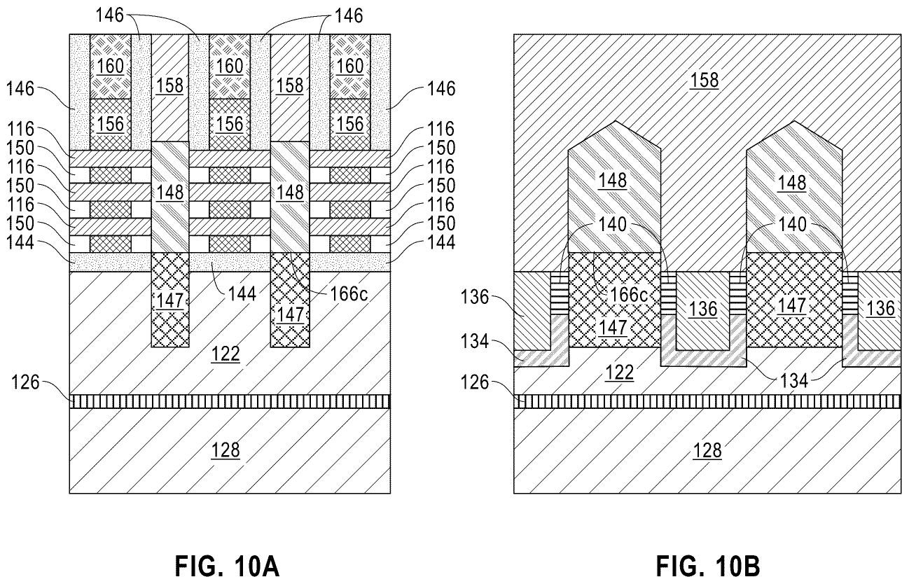

FIGS. 10A and 10B depict cross-sectional side views of the semiconductor structure 100 of FIG. 1 along line A-A′ and B-B′ at a subsequent fabrication stage of the processing method, in accordance with one embodiment of the present invention. The semiconductor structure 100 includes a high-x metal gate (HKMG) 156 and an interlayer dielectric (ILD) 158 (e.g., silicon oxide, other dielectric materials). Specifically, the dummy gate 142 has been removed completely from within the spacers 146; the sacrificial semiconductor layers 118 have been released; and the HKMG 156 has replaced the sacrificial semiconductor layer 118 and a portion of the bottom dummy gate structure 142b. A dielectric capping material 160 may also be filled into the spacers 146, for example to reduce the gate to source/drain shorting during contact RIE.

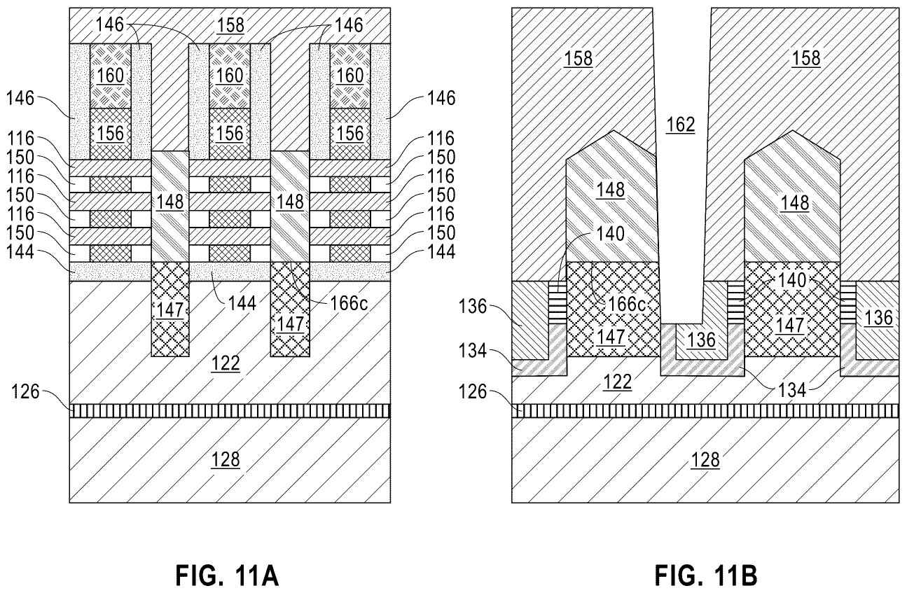

FIGS. 11A and 11B depict cross-sectional side views of the semiconductor structure 100 of FIG. 1 along line A-A′ and B-B′ at a subsequent fabrication stage of the processing method, in accordance with one embodiment of the present invention. The semiconductor structure 100 includes a contact trench 162 etched along a lateral side of the S/D 148. The contact trench 148 may be completed in whole or in part using a directional etch such as RIE. The contact trench 162 may also be etched using selective etch processes. For example, the ILD 158, the STI 136, the placeholder 147, and the STI spacer liner 140 may be etched without affecting the S/D 148, STI liner 134. In certain embodiments, the S/Ds 148 may be partially etched, and in certain other embodiments a selective etch that affects only the ILD 158 and the STI spacer liner 140 may be used. Additionally or alternatively, the contact trench 162 may be etched on both lateral sides of the S/D 148.

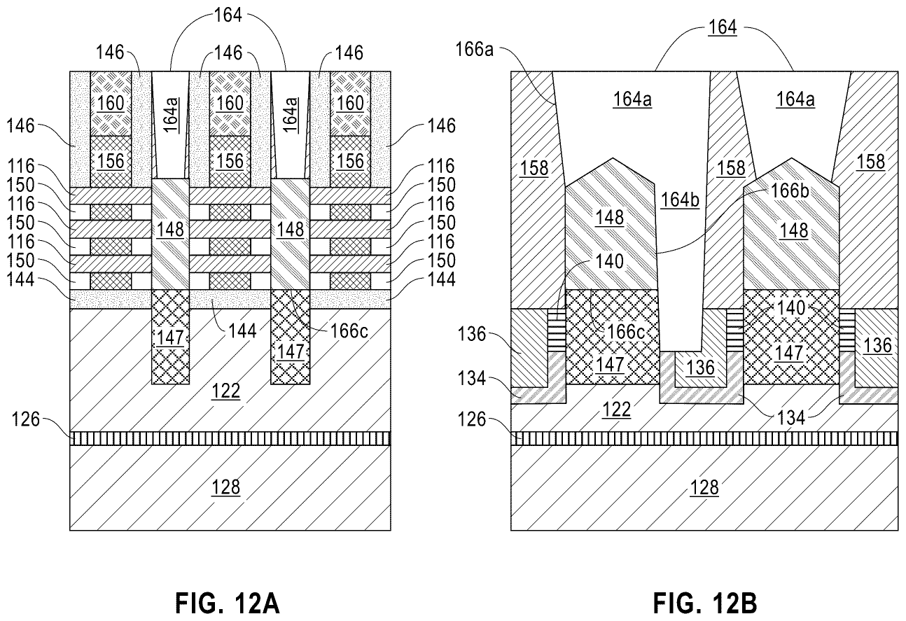

FIGS. 12A and 12B depict cross-sectional side views of the semiconductor structure 100 of FIG. 1 along line A-A′ and B-B′ at a subsequent fabrication stage of the processing method, in accordance with one embodiment of the present invention. The semiconductor structure 100 includes a contact 164 that includes two contact portions (so far, at this stage): a frontside contact 164a and a via contact 164b. Certain embodiments may also include a via contacts on the other lateral side of the S/D 148 as well. The via contact 164b is formed in the contact trench 162 from FIG. 11B, and the frontside contact 164a is formed in a frontside contact trench that may be formed in a different fabrication step. The metalizing of the contact 164 may be done in one stage (i.e., metalizing both the frontside contact 164a and the via contact 164b at the same time) or may be done in two stages (i.e., metalizing the via contact 164b in the contact trench 162 first, then cutting the frontside contact trench, and then metalizing the frontside contact 164a). The contact 164 contacts the S/D 148 on a top side 166a and a sidewall 166b, and may include a liner made of a metallic compound like nickel silicide or titanium silicide. The liner enhances the connection between the S/Ds 148 and the contacts 164 by reducing contact resistance. This lower resistance enables efficient electron flow, improving the electrical efficiency and performance of the transistor, which is crucial in high-performance semiconductor devices where low power consumption and high-speed operation are essential. The liner may also aid in the scalability of transistor technology as the FETs 106 continue to shrink.

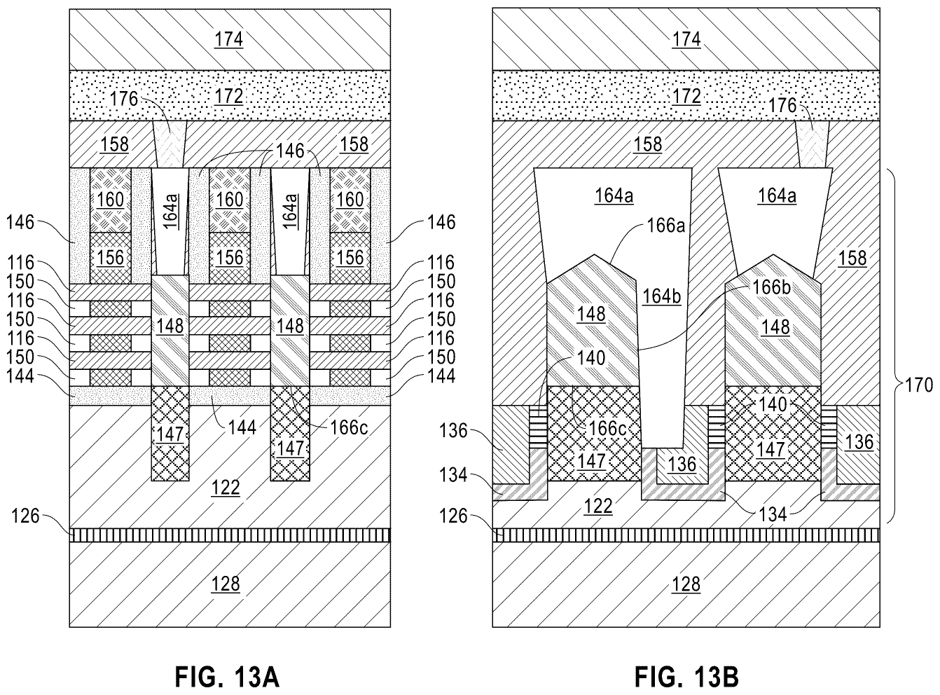

FIGS. 13A and 13B depict cross-sectional side views of the semiconductor structure 100 of FIG. 1 along line A-A′ and B-B′ at a subsequent fabrication stage of the processing method, in accordance with one embodiment of the present invention. The semiconductor structure 100 includes a back-end-of-line (BEOL) 172 that is fabricated above a device layer 170 that includes the components discussed above. The BEOL 172 connects the device layer 170 (and included FETs 106) to external power and communication sources, and includes many (e.g., dozens) of layers of wires, vias, and connects. The BEOL 172 layers are formed by first depositing insulating materials (typically silicon dioxide or low-k dielectrics) on top of the device layer 170, then using lithography and etching techniques to define patterns for metal interconnects and vias in this insulating layer. Subsequently, metal layers (commonly aluminum or copper) are deposited, and further lithography and etching steps are employed to shape these layers into interconnects and vias. This process is repeated to build multiple layers of insulating materials, metal interconnects, and vias as needed for the specific semiconductor technology and device, ultimately finishing with a top insulating layer and a carrier wafer 174 that serves to protect the metal interconnects and complete the BEOL 172. The BEOL 172 may be connected to specific contacts in the device layer 170 through contact vias 176 on the top side of the device layer 170.

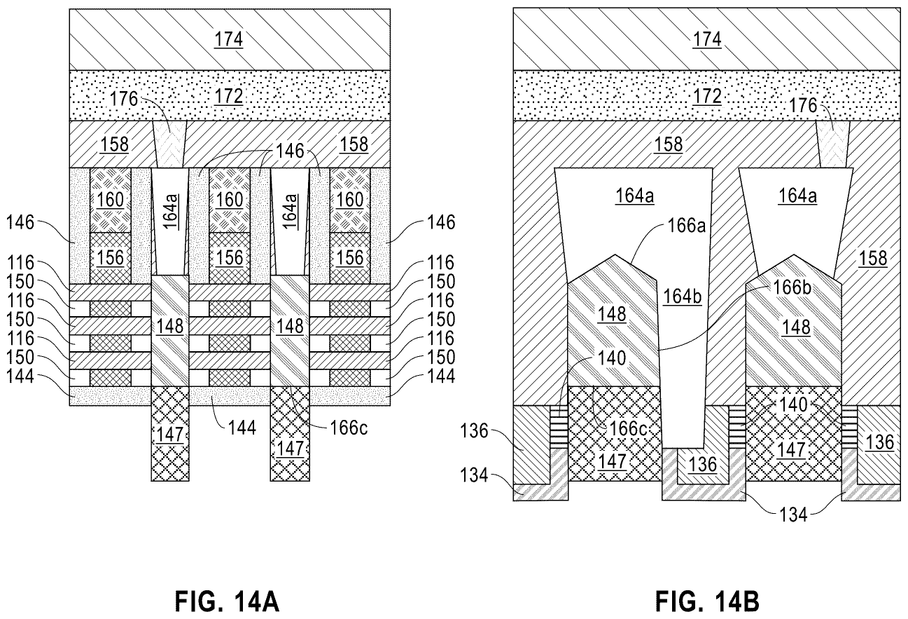

FIGS. 14A and 14B depict cross-sectional side views of the semiconductor structure 100 of FIG. 1 along line A-A′ and B-B′ at a subsequent fabrication stage of the processing method, in accordance with one embodiment of the present invention. The semiconductor structure 100 shows the removal of the backside of the device layer 170. The semiconductor structure 100 is often flipped over, with support provided by the carrier wafer 174 on the frontside of the BEOL 172. The backside of the device layer 170 may be removed in steps, with the structural substrate 128 being removed first through a rough etch process that is done with simultaneous monitoring of the etch stop layer 126. When the rough etch process contacts the etch stop layer 126, the rough etch stops. This saved the device layer 170 from damage since the rough etch process used to remove the structural substrate 128 could potentially damage the components in the device layer 170. The etch stop layer 126 and the substrate 122 are removed with selective etch processes that are finer than the rough etch process. These finer processes do not affect the STI liner 134 and the placeholders 147 etc.

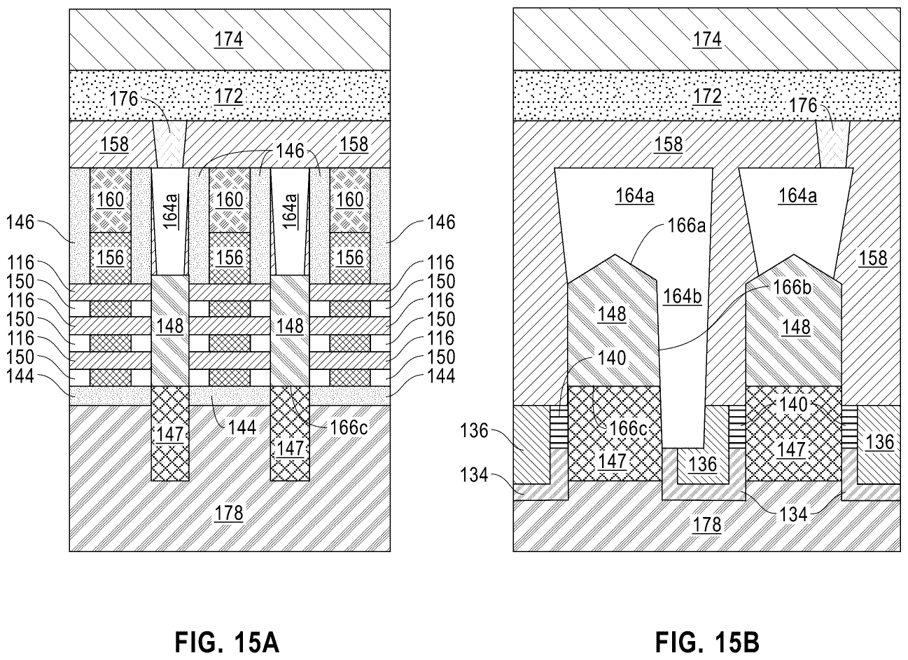

FIGS. 15A and 15B depict cross-sectional side views of the semiconductor structure 100 of FIG. 1 along line A-A′ and B-B′ at a subsequent fabrication stage of the processing method, in accordance with one embodiment of the present invention. The semiconductor structure 100 includes a backside ILD 178 that is formed over the backside of the device layer 170, replacing the semiconductor substrate 122 with a more insulative dielectric layer. The backside ILD 178 may include insulating materials used to electrically isolate different layers of interconnects and transistors. Common materials include silicon dioxide (SiO2), low-k dielectrics with lower dielectric constants, organosilicate glass (OSG), porous low-k dielectrics, and hybrid dielectrics. These materials serve to reduce signal delay, capacitance, and improve the overall performance of the semiconductor structure 100, with the choice depending on the specific technology and manufacturing requirements.

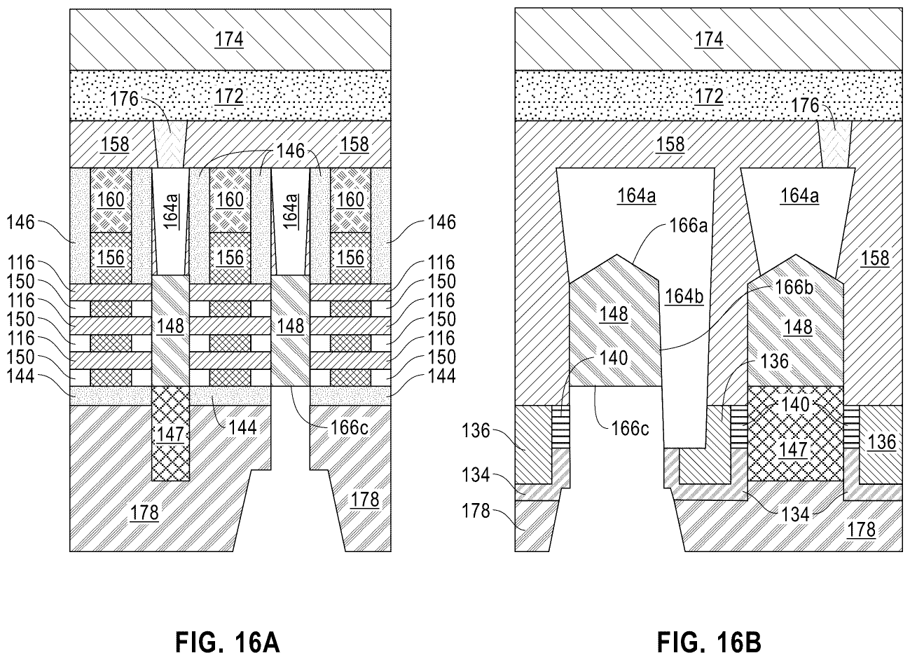

FIGS. 16A and 16B depict cross-sectional side views of the semiconductor structure 100 of FIG. 1 along line A-A′ and B-B′ at a subsequent fabrication stage of the processing method, in accordance with one embodiment of the present invention. The semiconductor structure 100 includes a backside contact trench 180 that is patterned into the backside ILD 178 and then expanded by removing the placeholder 147 through a selective etch process.

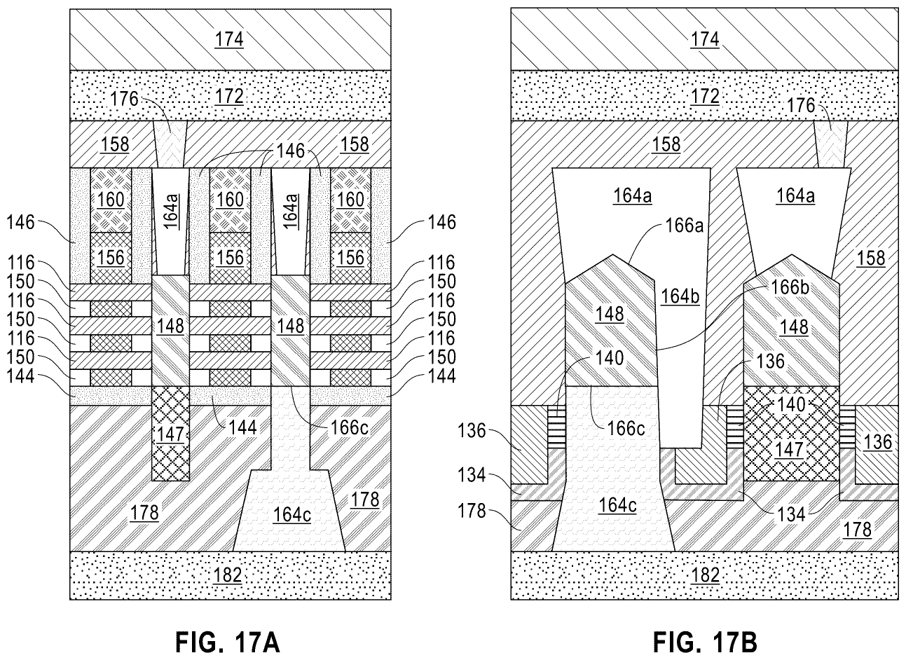

FIGS. 17A and 17B depict cross-sectional side views of the semiconductor structure 100 of FIG. 1 along line A-A′ and B-B′ at a subsequent fabrication stage of the processing method, in accordance with one embodiment of the present invention. The semiconductor structure 100 includes a backside contact 164c formed by metalizing within the backside contact trench 180, and a backside interconnect 182 formed on the backside of the device layer 170. The backside contact 164c contacts a backside 166c of the S/D 148, the via contact 164b, and the backside interconnect 182 as well. These contacts enable a low-resistance signal flow from the backside interconnect 182 to the S/D 148, which is further enhanced due to the wrap-around of the contact 164 on three of four sides of the S/D 148. The backside contact 164c is confined by the STI liner 134 on a first side and a second STI liner 134 on a second side. This confining provides a self-aligned function for the location of the backside contact 164c that fixes potential misalignment of the patterning for the backside contact 164c.

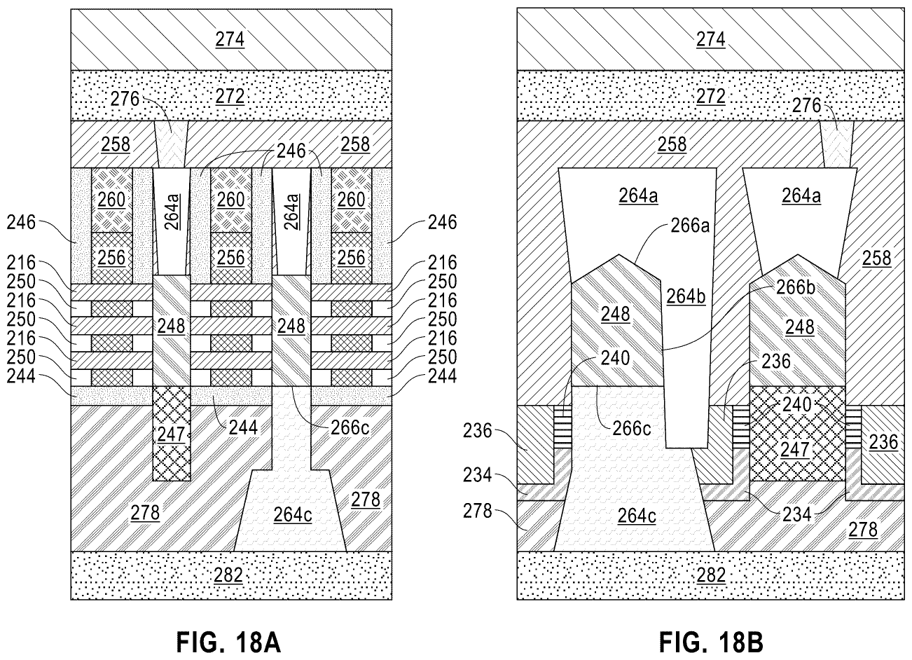

FIGS. 18A and 18B depict cross-sectional side views of a semiconductor structure 200 at a fabrication stage of a processing method, in accordance with one embodiment of the present invention. The semiconductor structure 200 includes the components of a device layer 270 described above, with a change to a contact 264. The contact 264 includes the three sections of the contact 164 above (i.e., a frontside contact 264a, a via contact 264b, and a backside contact 264c), with a change to the backside contact 264c. Specifically, the backside contact 264c is patterned with a wider pattern to provide additional overlap between the backside contact 264c and the via contact 264b. That is, the backside contact 264c cuts through a STI liner 234 and is thus confined by the STI liner 234 on the left side in the figure, and by the STI 236 on the right side of the figure. Certain embodiments may include via contacts 264b on both lateral sides of the S/Ds 248 for a “full wrap around” contact.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections or buried interconnections). In any case, the chip may be integrated with other chips, discrete circuit elements, and/or other signal processing devices as part of either an intermediate product or an end product.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a first source/drain (S/D) epitaxially grown in a device layer;
a frontside contact contacting a frontside of the first S/D;
a backside contact contacting a backside of the first S/D; and
a via contact contacting: i) a sidewall of the first S/D, ii) the frontside contact, and iii) the backside contact.

2. The semiconductor structure of claim 1, further comprising a shallow trench isolation (STI), a STI spacer liner, and a STI liner, wherein the STI spacer liner and the STI liner surround the STI.

3. The semiconductor structure of claim 2, wherein the via contact is etched into the STI spacer liner and not etched into the STI liner.

4. The semiconductor structure of claim 2, further comprising a second STI, wherein the backside contact is confined by the STI liner and the second STI.

5. The semiconductor structure of claim 2, further comprising a second STI liner, wherein the backside contact is confined by the STI liner and the second STI liner.

6. The semiconductor structure of claim 1, further comprising: a second via contact contacting a second sidewall of the first S/D.

7. The semiconductor structure of claim 1, further comprising:
a backside power delivery network (BSPDN) connected to the backside contact; and
a back-end-of-line (BEOL) connected to the frontside contact.

8. A method of fabricating a semiconductor structure, comprising:
forming a first source/drain (S/D) in a device layer;
forming a frontside contact contacting a frontside of the first S/D;
forming a backside contact contacting a backside of the first S/D;
forming a via contact contacting: i) a sidewall of the first S/D, ii) the frontside contact, and iii) the backside contact.

9. The method of claim 8, wherein the frontside contact and the via contact are metalized in one fabrication step.

10. The method of claim 8, further comprising:
forming an STI liner;
forming a shallow trench isolation (STI) within the STI liner;
recessing the STI liner; and
forming an STI spacer liner in the recess of the STI liner.

11. The method of claim 10, wherein the backside contact is confined by the STI spacer liner and a second STI liner.

12. The method of claim 10, further comprising etching the STI spacer liner on one side of the STI before forming the via contact.

13. The method of claim 8, wherein forming the backside contact comprises replacing a placeholder after forming the via contact.

14. The method of claim 8, further comprising:
forming a backside power delivery network on a backside of the device layer; and
forming a back-end-of-line on the frontside of the device layer.

15. A semiconductor structure, comprising:
a first source/drain (S/D) grown in a device layer; and
a first contact contacting the first S/D on a frontside, a backside, and a sidewall.

16. The semiconductor structure of claim 15, further comprising a shallow trench isolation (STI), a STI spacer liner, and a STI liner, wherein the STI spacer liner and the STI liner surround the STI.

17. The semiconductor structure of claim 16, wherein the via contact is etched into the STI spacer liner and not etched into the STI liner.

18. The semiconductor structure of claim 16, further comprising a second STI, wherein the backside contact is confined by the STI liner and the second STI.

19. The semiconductor structure of claim 15, further comprising a backside power delivery network (BSPDN) connected to the first contact on a backside of the device layer.

20. The semiconductor structure of claim 15, further comprising a back-end-of-line (BEOL) connected to the first contact on a frontside of the device layer.
